(19) United States
(12) Patent Application Publication
(10) Pub. No.: US 2026/0190543 A1
(43) Pub. Date: Jul. 2, 2026

(54) SINGLE-CHIP POLYCHROMATIC LIGHT-EMITTING DIODE AND LED BACKLIGHT SOURCE

(71) Applicant: Huaian Aucksun Optoelectronics Technology Co., Ltd, Huaian (CN)

(72) Inventors: Yuan GUO, Huaian City (CN); Daqian YE, Huaian City (CN); Weijie LIAN, Huaian City (CN); Changwei SONG, Huaian City (CN); Licheng HUANG, Huaian City (CN); Ling LU, Huaian City (CN)

(21) Appl. No.: 19/431,189

(22) Filed: Dec. 23, 2025

(30) Foreign Application Priority Data
Dec. 27, 2024 (CN) 202411945107.3

(51) Int. Cl. H10H 20/813; H10H 20/812; H10H 20/825

(52) U.S. Cl. CPC H10H 20/8131; H10H 20/812; H10H 20/8252

(57) ABSTRACT

A single-chip polychromatic light-emitting diode includes a polychromatic light-emitting layer disposed between an N-type layer and a P-type layer. The polychromatic light-emitting layer includes a first light-emitting layer emitting light of a first color and a second light-emitting layer emitting light of a second color, where the peak wavelength λp2 of the light of the second color is greater than the peak wavelength λp1 of the light of the first color, and λp2-λp1≥50 nm. The thickness of a second well layer in the second light-emitting layer is less than the thickness of a first well layer in the first light-emitting layer. The single-chip polychromatic light-emitting diode can emit light of at least two colors, and either does not use phosphors or uses fewer phosphors, so that the cost of RGB-LED backlight sources can be reduced.

### TECHNICAL FIELD

The present invention relates to the field of light-emitting diode technologies, and specifically, to a single-chip polychromatic light-emitting diode and an LED backlight source.

### BACKGROUND

Light-emitting diodes (LEDs) based on gallium nitride (GaN) III-V compound semiconductors typically exhibit excellent light emission characteristics. Theoretically, LED emission from GaN-based III-V compound semiconductors, such as InGaN, AlGaN, AlInGaN, and GaN, can cover the entire visible spectrum from short wavelengths (i.e., UV) to long wavelengths (i.e., red light). LEDs are widely used in fields such as signal lights, vehicle lights, landscapes, indoor lighting sources, and display screens. Existing LED backlight sources for display screens include RGB-LEDs and white LEDs. The RGB-LEDs are formed by packaging three monochromatic LED chips, i.e., blue, green, and red LED chips, together. For example, blue LED chips and green LED chips are group III nitride compound semiconductor elements, and red light-emitting elements are GaAs-based or GaN-based light-emitting elements. White LEDs are formed by combining monochromatic LED chips with phosphors. For example, a monochromatic blue light chip is combined with a green phosphor and a red phosphor, or a monochromatic blue LED chip is combined with a yellow phosphor. RGB three-primary-color LED backlight sources has the best display effect, but costs are high. White LEDs require a phosphor. As shown in FIG. 1, different phosphor solutions have significant differences in NTSC (National Television Standards Committee) color gamuts, and it is also difficult to control the uniformity after a phosphor is mixed with an adhesive, thus resulting in problems such as poor light emission uniformity, poor color tone consistency, easy deviation of color temperature, and unsatisfactory color rendering.

It is known that the NTSC color gamut is the ratio of a certain triangular region to a standard triangular region under an NTSC standard. The higher the ratio, the better the color performance. The high color gamut coverage often mentioned in the industry means that the NTSC color gamut ratio is greater than or equal to 85%. Moreover, white light having high color gamut coverage is generally achieved by a blue light chip, a green phosphor, and a red phosphor. Currently, green phosphor in the best solution for achieving high color gamut coverage is β-SiAlON, but the full width at half maximum thereof is still 48 nm to 55 nm. See FIG. 2.

Therefore, how to lower the cost of RGB-LED backlight sources and/or reduce the use of phosphors in white LED backlight sources, and maintain a high NTSC level is a technical problem to be solved.

In view of this, the present invention is hereby provided.

### SUMMARY

A first objective of the present invention is to provide a single-chip polychromatic light-emitting diode that can emit light of at least two colors on a single LED chip, and either does not use phosphors or uses fewer phosphors, so that the cost of RGB-LED backlight sources can be reduced.

A second objective of the present invention is to provide an LED backlight source.

To achieve the objectives of the present invention, the following technical solution is adopted:

The present invention first provides a single-chip polychromatic light-emitting diode, including a polychromatic light-emitting layer disposed between an N-type layer and a P-type layer.

The polychromatic light-emitting layer includes a first light-emitting layer emitting light of a first color and a second light-emitting layer emitting light of a second color. The peak wavelength λₚ₂ of the light of the second color is greater than the peak wavelength λₚ₁ of the light of the first color, and λₚ₂-λₚ₁≥50 nm.

The thickness of a second well layer in the second light-emitting layer is less than the thickness of a first well layer in the first light-emitting layer.

Preferably, the ratio of the thickness of the second well layer to the thickness of the first well layer is 0.5 to 0.95.

Preferably, the thickness of the second well layer is 27 Å to 32 Å.

Preferably, the thickness of the first well layer is 33 Å to 38 Å.

Preferably, the first well layer includes Inₓ₁Ga₍₁₋ₓ₁₎N, and the second well layer includes Inₓ₂Ga(₁₋ₓ₂)N, where 1>x2>x1>0.1.

Preferably, x2=0.22−0.28.

Preferably, x1=0.13−0.19.

Preferably, the light of the first color includes blue light, and the light of the second color includes green light.

Preferably, the peak wavelength λₚ₁ of the light of the first color is equal to 440 nm to 470 nm.

Preferably, the peak wavelength λₚ₂ of the light of the second color is equal to 520 nm to 550 nm.

Preferably, when an input current is greater than or equal to 10 mA, the ratio of the peak wavelength intensity of the light of the first color to the peak wavelength intensity of the light of the second color is greater than or equal to 5.

Preferably, the second light-emitting layer includes second barrier layers, and the first light-emitting layer includes first barrier layers.

Preferably, the thickness of the second barrier layer is greater than the thickness of the first barrier layer.

Preferably, the thickness of the second barrier layer is 100 Å to 200 Å.

Preferably, the thickness of the first barrier layer is 90 Å to 100 Å.

Preferably, the ratio of a sum H2 of the thickness of the second well layer and the thickness of the second barrier layer to a sum H1 of the thickness of the first well layer and the thickness of the first barrier layer, that is, H2/H1, is equal to 0.9 to 1.1.

Preferably, a ratio H3 of the thickness of the second barrier layer to the thickness of the second well layer is greater than or equal to a ratio H4 of the thickness of the first barrier layer to the thickness of the first well layer, and H3/H4=1−2.

Preferably, the first barrier layer in the first light-emitting layer includes at least one of GaN, AlGaN, or InAlGaN.

Preferably, the second barrier layer in the second light-emitting layer includes at least one of GaN, AlGaN, or InAlGaN.

Preferably, the number of first well layers is 10 to 20, and a first barrier layer is provided between every two adjacent first well layers.

Preferably, the number of second well layers is 1 to 5, and the second barrier layer is provided on each of two sides of each second well layer.

Preferably, the first light-emitting layer includes a first periodic structure in which first well layers and first barrier layers are alternately stacked, and the number of periods of the first periodic structure is 10 to 20.

Preferably, the second light-emitting layer includes a second periodic structure in which second well layers and second barrier layers are alternately stacked, and the number of periods of the second periodic structure is 1 to 5.

Preferably, the number of the first well layers is 4 times to 20 times the number of the second well layers.

Preferably, the energy band of the second well layer in the second light-emitting layer is lower than the energy band of the first well layer in the first light-emitting layer.

Preferably, the energy band of the second barrier layer in the second light-emitting layer is lower than the energy band of the first barrier layer in the first light-emitting layer.

Preferably, the direction from the N-type layer to the P-type layer is defined as a first direction, the energy band of the second barrier layer in the second light-emitting layer gradually increases in the first direction, and the energy band of the first barrier layer in the first light-emitting layer gradually decreases in the first direction.

Preferably, Al is doped between the second well layer and the second barrier layer in the second light-emitting layer.

Preferably, the thickness of Al is less than ⅓ of the thickness of the second well layer.

Preferably, when an injected current is 350 mA, the brightness of the single-chip polychromatic light-emitting diode is greater than or equal to 770 mW.

The present invention further provides an LED backlight source. The LED backlight source includes an RGB-LED and a white LED, and the RGB-LED or the white LED includes the single-chip polychromatic light-emitting diode.

Preferably, the RGB-LED includes the single-chip polychromatic light-emitting diode and a monochromatic red light-emitting diode.

Preferably, the white LED includes the single-chip polychromatic light-emitting diode, a fluorescent film layer, and a high-reflective white adhesive around the single-chip polychromatic light-emitting diode and the fluorescent film layer, where the fluorescent film layer includes a silicone layer and a red fluorescent layer; a red phosphor in the red fluorescent layer includes a nitride phosphor and/or a fluoride phosphor; and when the red phosphor is a fluoride phosphor, the red fluorescent layer is further provided with a silicone protective layer on the side away from the single-chip polychromatic light-emitting diode.

Compared with conventional technologies, the beneficial effects of the present invention are that:
(1) The single-chip polychromatic light-emitting diode provided by the present invention can emit light of at least two colors, and either does not use phosphors or uses fewer phosphors, so that the cost of RGB-LED backlight sources can be reduced.
(2) The single-chip polychromatic light-emitting diode provided by the present invention solves the problem of low internal quantum efficiency of a light-emitting element caused by an increase in nonradiative recombination due to poor quality of crystals of epitaxially grown buffer layer and light-emitting layer.
(3) When the single-chip polychromatic light-emitting diode provided by the present invention is applied to an LED backlight source, the single-chip polychromatic light-emitting diode and a monochromatic red light-emitting diode are jointly packaged to form an LED backlight source, or the single-chip polychromatic light-emitting diode and a red phosphor are jointly packaged to form a white LED backlight source, or the single-chip polychromatic light-emitting diode forms a light-emitting diode having a single chip and emitting red, green and blue light simultaneously, and then an LED backlight source having a high color gamut and high brightness is obtained.
(4) The single-chip polychromatic light-emitting diode provided by the present invention can improve the quality of the crystals by reducing the thickness of a blue light quantum barrier layer (the thickness of the first barrier layer).
(5) In the single-chip polychromatic light-emitting diode provided by the present invention, a structure in which thick barriers and thin wells are provided is adopted in the second light-emitting layer, which can reduce energy band distortion and improve an average energy band.
(6) In the single-chip polychromatic light-emitting diode provided by the present invention, H 3/H4 is set to be equal to 1 to 2, which can make the average energy band of the first light-emitting layer close to the average energy band of the second light-emitting layer, thereby improving light-emitting efficiency.
(7) In the single-chip polychromatic light-emitting diode provided by the present invention, the thickness of the second well layer is set to be less than the thickness of the first well layer, the brightness of the chip is higher than that of an LED chip in which blue light wells and green light wells have a same thickness, and the brightness is increased by at least 10%.

### BRIEF DESCRIPTION OF THE DRAWINGS

To describe the technical solutions in specific embodiments of the present invention or in conventional technologies more clearly, the following briefly describes the accompanying drawings required for describing specific embodiments or conventional technologies. Apparently, the accompanying drawings in the following description show some embodiments of the present invention, and a person of ordinary skill in the art may still derive other drawings from these accompanying drawings without creative efforts.

FIG. 1 shows white light implementation schemes with different NTSC values provided by the present invention;

FIG. 2 shows peak wavelength and full width at half maximum parameters of LED phosphors of different systems provided by the present invention;

FIG. 3 is a diagram of a first structure of a polychromatic light-emitting layer provided by the present invention;

FIG. 4 is a diagram of a second structure of the polychromatic light-emitting layer provided by the present invention;

FIG. 5 is a diagram of a third structure of the polychromatic light-emitting layer provided by the present invention;

FIG. 6 is a diagram of a fourth structure of the polychromatic light-emitting layer provided by the present invention;

FIG. 7 is a diagram of a fifth structure of the polychromatic light-emitting layer provided by the present invention;

FIG. 8 is a diagram of a sixth structure of the polychromatic light-emitting layer provided by the present invention;

FIG. 9 is a diagram of a structure of a single-chip polychromatic light-emitting diode provided by the present invention;

FIG. 10 is a sectional view of a structure of a wire-bonded LED chip provided by the present invention;

FIG. 11 is a sectional view of a structure of a flip LED chip provided by the present invention;

FIG. 12 is a diagram of a structure of a white LED provided by the present invention;

FIG. 13 is a diagram of another structure of the white LED provided by the present invention;

FIG. 14 shows an optical power spectrum distribution under different currents provided by the present invention; and

FIG. 15 shows an normalized relative intensity spectrum of green light provided by the present invention.

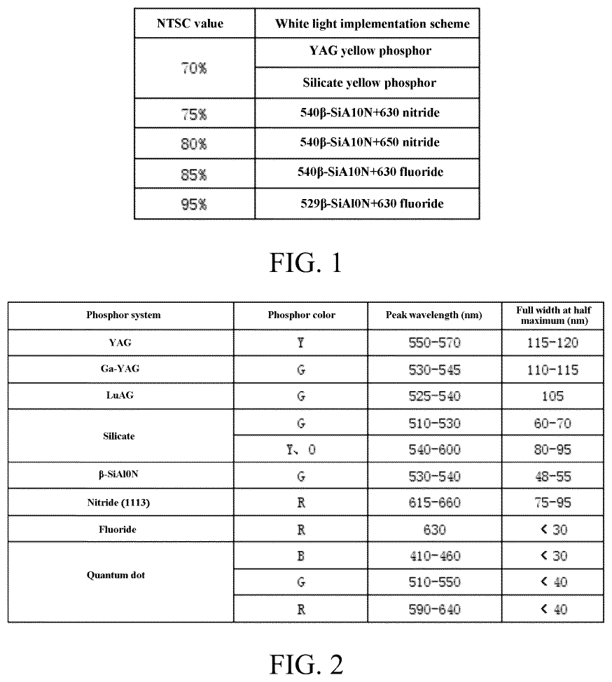

### REFERENCE NUMERALS

100-substrate; 101-first buffer layer; 102-second buffer layer; 103-third buffer layer; 110-N-type layer; 120-polychromatic light-emitting layer; 121-first light-emitting layer; 122-second light-emitting layer; 130-P-type layer; 210-current blocking layer; 220-ohmic contact layer; 230-P-type electrode; 240-N-type electrode; 250-insulating protective layer; 261-first P electrode; 262-second P electrode; 271-first N electrode; 272-second N electrode.

### DETAILED DESCRIPTION

The following clearly and completely describes the technical solutions of the present invention with reference to accompanying drawings and specific embodiments. However, a person skilled in the art understands that the embodiments described below are some but not all of embodiments, are only intended to illustrate the present invention, and are not to be considered as limiting the scope of the present invention. All other embodiments obtained by a person of ordinary skill in the art based on embodiments of the present invention without creative efforts shall fall within the protection scope of the present invention. Embodiments in which specific conditions are not specified shall be performed in accordance with conventional conditions or conditions recommended by manufacturers. The used reagents or instruments, the manufacturers of which are not specified, are all conventional products that can be purchased commercially.

Unless otherwise specified, in the present invention, the terms such as “first aspect”, “second aspect”, “third aspect”, and “fourth aspect” are merely used for description, cannot be understood as an indication or implication of relative importance or a quantity, and likewise cannot be understood as an implicit indication of importance or a quantity of indicated technical features. Moreover, the terms such as “first,” “second,” “third,” and “fourth” are merely used for non-exhaustive enumerations and should be understood as not constituting a closed limitation on a quantity.

Unless otherwise specified, the terms “comprising” and “including” mentioned in the present invention means an open end or a closed end. For example, the terms “comprising” and “including” may mean that other components not listed may also be comprised or included, or that only listed components may be comprised or included.

Unless otherwise specified, in the present invention, the term “one or multiple” or “at least one” refers to any one, any two, or any two or more of listed items. The term “multiple” refers to any two or more.

According to a first aspect, the present invention provides a single-chip polychromatic light-emitting diode, including an N-type layer 110, a P-type layer 130, and a polychromatic light-emitting layer 120 disposed between the N-type layer 110 and the P-type layer 130.

The polychromatic light-emitting layer 120 includes a first light-emitting layer 121 emitting light of a first color and a second light-emitting layer 122 emitting light of a second color.

The peak wavelength λₚ₂ of the light of the second color is greater than the peak wavelength λₚ₁ of the light of the first color, and λₚ₂-λₚ₁≥50 nm.

The value of λp2-λp1 includes but is not limited to any specific value among or a range value between any two of 50 nm, 60 nm, 70 nm, 80 nm, 90 nm, 100 nm, 110 nm, 120 nm, 130 nm, 140 nm, and 150 nm.

Further, the thickness of a second well layer (referring to the thickness of a single layer) in the second light-emitting layer 122 is less than the thickness of a first well layer (referring to the thickness of a single layer) in the first light-emitting layer 121.

The light-emitting diode that has a single chip and can emit multiple different colors provided by the present invention can emit light of at least two colors, and either does not use phosphors or uses fewer phosphors, so that the cost of RGB-LED backlight sources can be reduced.

LED emission from GaN-based III-V compound semiconductors, such as InGaN, AlGaN, AlInGaN, and GaN, can cover the entire visible spectrum from short wavelengths (i.e., UV) to long wavelengths (i.e., red light). For example, by adjusting the In concentration in a light-emitting well layer, light of different colors/wavelengths is emitted. Theoretically, the higher the In concentration, the longer the wavelength.

For example, in a blue and green dichromatic LED chip, the core structure is the superposition and growth of a green MQW (quantum well) structure and a blue MQW structure. Because the In concentration in the green MQW is much higher than the In concentration in the blue MQW, strong stress will be generated inside the two MQW structures during superposition and growth, resulting in poor growth quality and affecting product performance. By controlling the thickness of the second well layer to be less than the thickness of the first well layer, the present application solves the problem of low internal quantum efficiency of a light-emitting element caused by an increase in nonradiative recombination due to poor quality of crystals of epitaxially grown buffer layer and light-emitting layer.

In some specific embodiments, the single-chip polychromatic light-emitting diode provided by the present invention includes at least a green light-emitting layer and a blue light-emitting layer, and the light-emitting diode has a green light emission peak and a blue light emission peak after being powered on. That is, the light of the first color includes blue light, and the light of the second color includes green light.

When applied to an LED backlight source, the blue-green light-emitting diode of the present application and a monochromatic red light-emitting diode are jointly packaged to form an LED backlight source. Alternatively, the blue-green light-emitting diode of the present application and a red phosphor are jointly packaged to form a white LED backlight source, or in the present application, a light-emitting diode that has a single chip and can emit red, green and blue light simultaneously can be formed. Then an LED backlight source having a high color gamut and high brightness is obtained.

In some specific embodiments, the ratio of the thickness of the second well layer to the thickness of the first well layer is 0.5 to 0.95, including but not limited to any specific value among or a range value between any two of 0.5, 0.55, 0.6, 0.65, 0.7, 0.75, 0.8, 0.85, 0.9, and 0.95; preferably 0.8 to 0.9. By regulating the ratio of the thickness of the second well layer to the thickness of the first well layer, the stress in MQWs and crystal quality can be controlled, thereby regulating brightness.

In some specific embodiments, the thickness of the second well layer is 27 Å to 32 Å, including but not limited to any specific value among or a range value between any two of 27 Å, 28 Å, 29 Å, 30 Å, 31 Å, and 32 Å.

In some specific embodiments, the thickness of the first well layer is 33 Å to 38 Å, including but not limited to any specific value among or a range value between any two of 33 Å, 34 Å, 35 Å, 36 Å, 37 Å, and 38 Å.

In some specific embodiments, the first well layer includes Inₓ₁Ga₍₁₋ₓ₁₎N, and the second well layer includes Inₓ₂Ga₍₁₋ₓ₂₎N, where 1>x2>x1>0.1, that is, the In concentration in the second well layer is greater than the In concentration in the first well layer. The value of x2 or x1 includes but is not limited to any specific value among or a range value between any two of 0.11, 0.13, 0.15, 0.2, 0.25, 0.3, 0.35, 0.4, 0.45, 0.5, 0.6, 0.7, 0.8, and 0.9.

By adjusting the In concentration in a light-emitting well layer, light of different colors/wavelengths is emitted. Theoretically, the higher the In concentration, the longer the wavelength.

In some specific embodiments, x2=0.22−0.28, including but not limited to any specific value among or a range value between any two of 0.22, 0.23, 0.24, 0.25, 0.26, 0.27, and 0.28.

In some specific embodiments, x1=0.13−0.19, including but not limited to any specific value among or a range value between any two of 0.13, 0.14, 0.15, 0.16, 0.17, 0.18, and 0.19.

In some specific embodiments, the light of the first color includes blue light, and the light of the second color includes green light.

In some specific embodiments, the peak wavelength λₚ₁ of the light of the first color is equal to 440 nm to 470 nm, including but not limited to any specific value among or a range value between any two of 440 nm, 450 nm, 460 nm, and 470 nm.

In some specific embodiments, the peak wavelength λₚ₂ of the light of the second color is equal to 520 nm to 550 nm, including but not limited to any specific value among or a range value between any two of 520 nm, 530 nm, 540 nm, and 550 nm.

In some specific embodiments, to meet the high color gamut requirement of a white LED, when an input current is greater than or equal to 10 m A, the ratio of the peak wavelength intensity of the light of the first color to the peak wavelength intensity of the light of the second color is greater than or equal to 5, including but not limited to any specific value among or a range value between any two of 5, 6, 7, 8, 9, 10, 11, 12, 13, 14, and 15, preferably 5 to 10.

In some specific embodiments, the thickness of a second barrier layer (referring to the thickness of a single layer) in the second light-emitting layer 122 is greater than the thickness of a first barrier layer (referring to the thickness of a single layer) in the first light-emitting layer 121. By reducing the thickness of a blue light quantum barrier layer (the thickness of the first barrier layer), the present invention can improve crystal quality and increase brightness.

In some specific embodiments, the thickness of the second barrier layer is 100 Å to 200 Å, including but not limited to any specific value among or a range value between any two of 100 Å, 110 Å, 120 Å, 130 Å, 140 Å, 150 Å, 160 Å, 170 Å, 180 Å, 190 Å, and 200 Å.

In some specific embodiments, the thickness of the first barrier layer is 90 Å to 100 Å, including but not limited to any specific value among or a range value between any two of 90 Å, 91 Å, 92 Å, 93 Å, 94 Å, 95 Å, 96 Å, 97 Å, 98 Å, 99 Å, and 100 Å.

In some specific embodiments, the ratio of a sum H2 of the thickness of the second well layer and the thickness of the second barrier layer to a sum H1 of the thickness of the first well layer and the thickness of the first barrier layer, that is, H2/H1, is equal to 0.9 to 1.1, including but not limited to any specific value among or a range value between any two of 0.9, 0.95, 1, 1.01, 1.03, 1.05, 1.06, 1.08, and 1.1, preferably H2/H1=1−1.1.

It may be understood that when H2/H1=1, the sum of the thickness of the second well layer and the thickness of the second barrier layer is equal to the sum of the thickness of the first well layer and the thickness of the first barrier layer.

Preferably, the sum H2 of the thickness of the second well layer and the thickness of the second barrier layer is greater than the sum H1 of the thickness of the first well layer and the thickness of the first barrier layer, that is, H2/H1 is preferably greater than 1. A structure in which thick barriers and thin wells are provided is adopted in a green light-emitting layer (i.e., the second light-emitting layer 122), which can reduce energy band distortion and improve an average energy band.

In some specific embodiments, a ratio H3 of the thickness of the second barrier layer to the thickness of the second well layer is greater than or equal to a ratio H4 of the thickness of the first barrier layer to the thickness of the first well layer (i.e., H3≥H4), preferably the ratio H3/H4 of the two is equal to 1 to 2, including but not limited to any specific value among or a range value between any two of 1, 1.05, 1.1, 1.2, 1.3, 1.4, 1.5, 1.6, 1.7, 1.8, 1.9, and 2. This can make the average energy band of the first light-emitting layer 121 close to the average energy band of the second light-emitting layer 122, thereby improving light-emitting efficiency.

In some specific embodiments, the first barrier layer in the first light-emitting layer 121 includes at least one of GaN, AlGaN, or InAlGaN.

In some specific embodiments, the second barrier layer in the second light-emitting layer 122 includes at least one of GaN, AlGaN, or InAlGaN.

The composition of the first barrier layer and the composition of the second barrier layer may be the same or different. This is not limited in the present invention.

In some specific embodiments, the number of first well layers is 10 to 20, preferably 10 to 15, and a first barrier layer is provided between every two adjacent first well layers.

In some specific embodiments, the number of second well layers is 1 to 5, preferably 1 to 3, and second barrier layers are provided on both adjacent upper and lower sides of any second well layer.

In some specific embodiments, the first light-emitting layer 121 includes a first periodic structure in which first well layers and first barrier layers are alternately stacked, preferably, the number of periods of the first periodic structure is 10 to 20, including but not limited to any specific value among or a range value between any two of 10, 11, 12, 13, 14, 15, 16, 17, 18, 19, and 20.

In some specific embodiments, the second light-emitting layer 122 includes a second periodic structure in which second well layers and second barrier layers are alternately stacked, more preferably, the number of periods of the second periodic structure is 1 to 5, including but not limited to any specific value among or a range value between any two of 1, 2, 3, 4, and 5.

In some specific embodiments, the number of first well layers is 4 times to 20 times the number of the second well layers, including but not limited to any specific value among or a range value between any two of 4 times, 5 times, 6 times, 7 times, 8 times, 10 times, 12 times, 13 times, 14 times, 15 times, 16 times, 18 times, and 20 times, preferably 6 to 15 times.

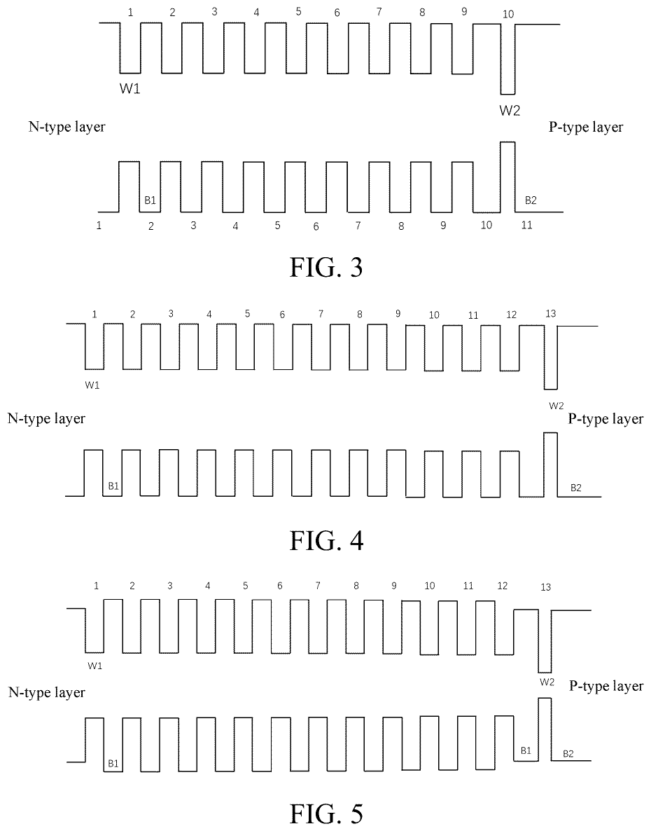

In some specific embodiments, with reference to FIG. 3, the polychromatic light-emitting layer 120 includes 9 first well layers (denoted as W1) and 1 second well layer (denoted as W2), that is, a total of 10 light-emitting well layers, and a light-emitting barrier layer is provided between every two adjacent light-emitting well layers. The 9 first well layers are close to the N-type layer 110 and emit blue light. The second well layer is closest to the P-type layer 130 and emits green light. The In concentration in the second well layer is greater than the In concentration in the first well layer, and the thickness of the second well layer is less than the thickness of the first well layer. Both a first well layer W1 and a second well layer W2 are made of InGaN material. The difference is that the In content in the second well layer is greater than that in the first well layer, so that the first well layer and the second well layer emit light of different wavelengths.

A first barrier layer (denoted as B1) is provided between every two adjacent first well layers and between the last first well layer and the first second well layer, and a second barrier layer (denoted as B2) is provided between the second well layer and the P-type layer 130. The thickness of the second barrier layer is greater than the thickness of the first barrier layer. Both the first barrier layer and the second barrier layer are GaN layers.

In some specific embodiments, with reference to FIG. 4, the polychromatic light-emitting layer 120 includes 12 first well layers (denoted as W1) and 1 second well layer (denoted as W2), that is, a total of 13 light-emitting well layers. The 12 first well layers close to the N-type layer 110 are blue light well layers. The second well layer close to the P-type layer 130 is a green light well layer. A first barrier layer (denoted as B1) is provided between every two adjacent first well layers. A second barrier layer (denoted as B2) is provided on the side of the second well layer close to the P-type layer 130. The thickness of the second well layer is less than the thickness of the first well layer, and the number of first well layers W1 is 12 times the number of second well layers W2. The sum H2 of the thickness of the second barrier layer and the thickness of the second well layer is greater than the sum H1 of the thickness of the first barrier layer and the thickness of the first well layer, that is, H2/H1 is greater than 1. The thickness of the second barrier layer is greater than the thickness of the first barrier layer. Both the first barrier layer and the second barrier layer are GaN layers.

In some specific embodiments, the energy band of the second well layer in the second light-emitting layer 122 is lower than the energy band of the first well layer in the first light-emitting layer 121. Thus, the light emission wavelength of the second light-emitting layer 122 is longer than that of the first light-emitting layer 121.

In some specific embodiments, the energy band of the second barrier layer in the second light-emitting layer 122 is lower than the energy band of the first barrier layer in the first light-emitting layer 121. This can alleviate the (quantum-confined Stark effect) QCSE effect in the second light-emitting layer 122.

In some specific embodiments, the first barrier layer is an AlGaN+GaN blue light barrier layer, for example, GaN is grown first, then AlGaN is grown, and then GaN is grown. The second barrier layer is a GaN green light barrier layer, but may also contain AlGaN, and the Al content of the second barrier layer is lower than that of the first barrier layer.

In some specific embodiments, with reference to FIG. 5, the polychromatic light-emitting layer 120 includes 12 first well layers and 1 second well layer, that is, a total of 13 light-emitting well layers. The thickness of the second well layer is less than the thickness of the first well layer, and the number of the first well layers is 12 times the number of the second well layers. The first light-emitting layer 121 is disposed at the end close to the N-type layer 110, and the second light-emitting layer 122 is disposed at the end close to the P-type layer 130. The second barrier layer (denoted as B2) is provided on each of two sides of the second well layer. The energy level of at least one of the first barrier layers (denoted as B1) between adjacent first well layers is higher than the energy level of the second barrier layer. For example, at least one first barrier layer is an AlGaN layer or an InAlGaN layer, and the second barrier layer is a GaN layer. The thickness of the second barrier layer is greater than the thickness of the first barrier layer.

In some specific embodiments, the direction from the N-type layer 110 to the P-type layer 130 is defined as a first direction, and the energy band of the second barrier layer gradually increases in the first direction, for example, GaN is grown first, and then AlGaN is grown, or InGaN having low In component content is grown first, and then GaN is grown. This can alleviate the severe quantum-confined Stark effect (QCSE effect) in the second light-emitting layer 122.

In some specific embodiments, the energy band of the first barrier layer gradually decreases in the first direction, for example, AlGaN is grown first, and then GaN is grown, or GaN is grown first, and then InGaN having low In component content is grown. This can improve the quality of a growth interface between the barrier layer and the well layer in the first light-emitting layer 121.

In some specific embodiments, Al is doped between the second well layer and the second barrier layer in the second light-emitting layer 122. That is, in the second light-emitting layer 122, a small amount of Al is doped at the junction between the second well layer and the second barrier layer. This can reduce the leakage current of a device.

In some specific embodiments, the thickness of Al is less than ⅓ of the thickness of the second well layer.

In some specific embodiments, when an injected current is 350 mA, the brightness of the single-chip polychromatic light-emitting diode is greater than or equal to 770 mW, including but not limited to any specific value among or a range value between any two of 770 mW, 775 mW, 780 mW, 785 mW, 790 mW, and 800 mW, preferably 770 mW to 790 mW.

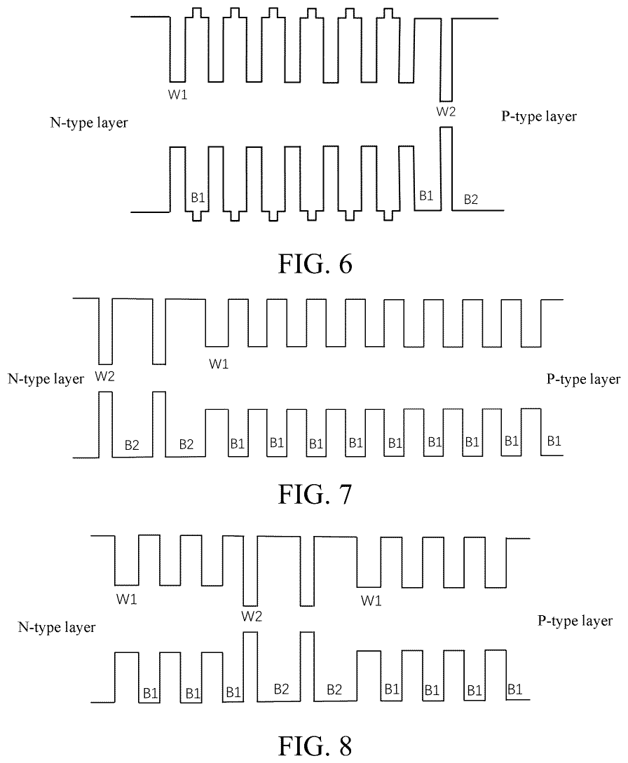

In some specific embodiments, with reference to FIG. 6, the first light-emitting layer 121 is disposed at the end close to the N-type layer 110, and the second light-emitting layer 122 is disposed at the end close to the P-type layer 130. A first barrier layer is provided between every two adjacent first well layers, and a second barrier layer is provided on the side of the second well layer close to the P-type layer 130. The first barrier layer is a GaN/AlGaN/GaN structure (protrusions in FIG. 6 are made of AlGaN, the presence of Al increases the energy level, and the blocking capability of the barrier layer as a blocking layer is increased), and the second barrier layer is made of GaN.

In some specific embodiments, the second light-emitting layer 122 may be located between the first light-emitting layer 121 and the P-type layer 130, or may be located between the N-type layer 110 and the first light-emitting layer 121. As shown in FIG. 7, the second light-emitting layer 122 emitting light of a long wavelength is closer to the N-type layer 110 and includes several alternately stacked second well layers W2 and second barrier layers B2; and the first light-emitting layer emitting light of a short wavelength is closer to the P-type layer 130 and includes several alternately stacked first well layers W1 and first barrier layers B1, where the thickness of the second well layer W2 is less than the thickness of the first well layer W1, and the thickness of the second barrier layer B2 is greater than the thickness of the first barrier layer B1. In addition, the sum of the thickness of the first barrier layer and the thickness of the first well layer in one period is less than the sum of the thickness of the second barrier layer and the thickness of the second well layer in one period. The number of the first well layers is greater than that of the second well layers, and the luminous intensity of the first light-emitting layer 121 is greater than the luminous intensity of the second light-emitting layer 122.

In some specific embodiments, the second light-emitting layer 122 is located in the middle of the first light-emitting layer 121, as shown in FIG. 8.

The relative position of the first light-emitting layer 121 and the second light-emitting layer 122 is related to the number of the second well layers. When the number of the second well layers (green light wells) is greater than 3, the second light-emitting layer 122 is disposed at the end close to the N-type layer 110; and when the number of the second well layers (green light wells) is less than 3, the second light-emitting layer 122 is disposed at the end close to the P-type Layer 130.

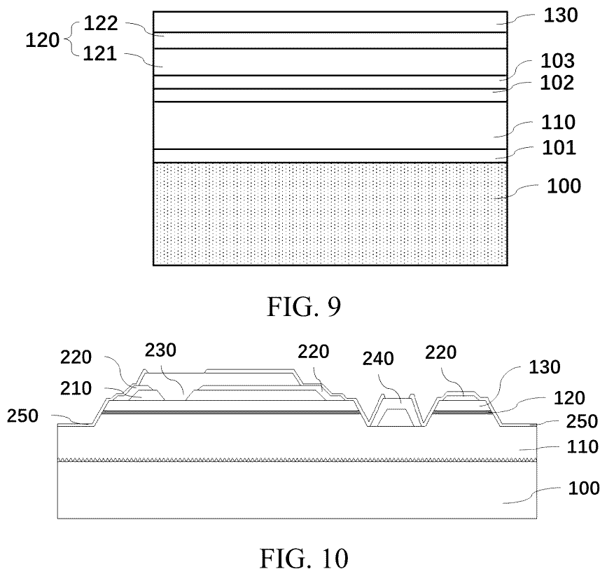

In some specific embodiments, with reference to FIG. 9, an epitaxial structure layer of the single-chip polychromatic light-emitting diode includes at least a substrate 100, and a first buffer layer 101, an N-type layer 110, a second buffer layer 102, a third buffer layer 103, a first light-emitting layer 121, a second light-emitting layer 122, and a P-type layer 130 sequentially grown on the substrate 100. The substrate 100 includes a sapphire substrate 100, a silicon substrate 100, a GaN substrate 100, a GaAS substrate 100, and the like. The first buffer layer 101 is at least one of an AlN layer, a GaN layer, or an AlGaN layer, and is configured to alleviate lattice mismatch between the sapphire substrate 100 and the N-type layer 110 when the material of the substrate 100 is inconsistent with an N-type material, for example, when the substrate 100 is made of sapphire. The N-type layer 110 is usually an n-type impurity-doped nitride semiconductor layer, such as a Si-doped GaN layer, and is configured to provide electrons. The second buffer layer 102 and the second buffer layer 102 are located between the polychromatic light-emitting layer 120 and the N-type layer 110 and achieve buffering and transition effects, and the second buffer layer 102 and the third buffer layer 103 are usually structures of alternating InGaN layers and GaN layers, where the In content of the InGaN layer in the second buffer layer 102 is less than the In content of the InGaN layer in the third buffer layer 103, and the In content of the InGaN layer in the third buffer layer 103 is less than the In content in the well layer of the polychromatic light-emitting layer 120. The P-type layer 130 is usually a P-type impurity-doped nitride layer, such as a Mg-doped GaN layer, and is configured to provide holes.

In some specific embodiments, according to requirements, an epitaxial structure may be prepared into a chip of a wire-bonded structure, a chip of a flip structure, a chip of a vertical structure, and a chip of a high-voltage structure. Although the structure types of the chips are different, the chips each include a P electrode (P-PAD) electrically connected to the P-type layer 130, and an N electrode electrically connected to an N-type GaN layer. The P electrode and the N electrode are connected to an external power supply, and emit light under the action of an externally applied current. The light-emitting efficiency of the light-emitting layer varies under different currents.

FIG. 10 shows a diagram of a structure of a wire-bonded LED chip, including a P-type electrode 230 electrically connected to a P-type layer 130, and an N-type electrode 240 electrically connected to an N-type layer 110; an insulating protective layer 250 is disposed on the LED chip, and openings exposing the P-type electrode 230 and the N-type electrode 240 are provided; a current blocking layer 210 is further provided between the P-type electrode 230 and the P-type layer 130, an ohmic contact layer 220 is provided on the current blocking layer 210, the current blocking layer 210 is a film layer formed by one or more of SiO₂, SiN₂, Al₂O₃ and TiO₂ materials, and the shape thereof is basically the same as that of the P electrode. The ohmic contact layer 220 is usually one or more of a conductive transparent film layer or a conductive reflective film layer, and in a wire-bonded product, it is usually a transparent conductive film layer and made of ITO.

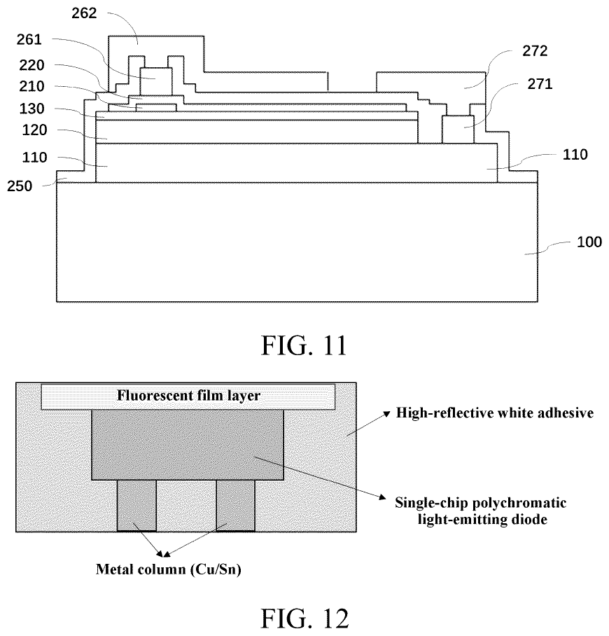

FIG. 11 shows a diagram of a structure of a flip LED chip. In a flip-chip structure, an ohmic contact layer 220 may be one or more of an ITO transparent conductive layer or an Ag reflective layer or an Al reflective layer, such as an ITO layer and an Ag reflective layer; and an insulating protective layer 250 and a current blocking layer 210 may be single protective film layers, and may also include distributed Bragg reflective layers. A second P electrode 262 and a second N electrode 272 are electrically connected to a first P electrode 261 and a first N electrode 271 respectively by means of openings of the insulating protective layer.

In some specific embodiments, when the size of a chip is 25×51 mil² and an injected current is 350 mA, the brightness of a monochromatic blue LED chip is 890 mW to 900 mW, the brightness of a blue-green LED chip in which the thickness of a blue light well (i.e., a first well layer) is equal to that of a green light well (i.e., a second well layer) is 680 mW to 700 mW, and the brightness of the blue-green LED chip of the structure of the present invention (the green light well is thin, that is, the thickness of the second well layer is less than the thickness of the first well layer) is 770 mW to 790 mW. Hence, the brightness of the single-chip polychromatic light-emitting diode chip provided by the present invention is higher than that of the blue-green LED chip in which the thickness of the blue light well is the same as that of the green light well. Brightness is increased by at least 10%.

In a second aspect, the present invention provides an LED backlight source. The LED backlight source includes an RGB-LED and a white LED, and the RGB-LED or the white LED includes the single-chip polychromatic light-emitting diode.

In some specific embodiments, the RGB-LED includes the single-chip polychromatic light-emitting diode and a monochromatic red light-emitting diode.

In some specific embodiments, the white LED is formed by combining the single-chip polychromatic light-emitting diode with a phosphor.

In some specific embodiments, the white LED includes the single-chip polychromatic light-emitting diode, a fluorescent film layer, and a high-reflective white adhesive around the single-chip polychromatic light-emitting diode and the fluorescent film layer. The fluorescent film layer includes a silicone layer and a red fluorescent layer.

The white LED is formed by packaging the single-chip polychromatic light-emitting diode. FIG. 12 shows a chip-level package. A fluorescent film layer is provided on a light-emitting surface of a blue-green dual-wavelength LED chip of a flip-chip structure, and a high-reflective white adhesive is provided around the fluorescent film layer and the LED chip. The fluorescent film layer is a wavelength conversion film layer formed by mixing silicone and a red fluorescent film.

In some specific embodiments, the red phosphor in the red fluorescent layer includes a nitride phosphor and/or a fluoride phosphor.

In some specific embodiments, when the red phosphor is a fluoride phosphor, a silicone protective layer is further provided on the side of the red fluorescent layer away from the single-chip polychromatic light-emitting diode.

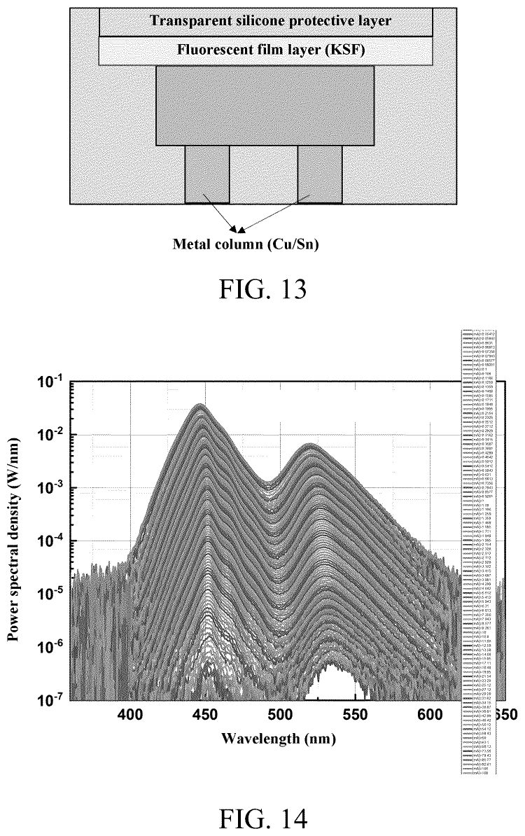

When the phosphor is a KSF fluorescent film, to protect the KSF fluorescent film layer, a transparent silicone protective layer may be first provided on a light-emitting surface of the fluorescent film layer, and then a high-reflective white adhesive may be provided, as shown in FIG. 13. An KSF phosphor (K₂SiF₆:Mn⁴⁺) is a fluoride system phosphor, and will undergo very serious degradation in high-temperature and high-humidity degradation and high-temperature environments, which manifests as brightness decay and color shift. In the present invention, provision of a transparent silicone protective layer can solve the problems of “brightness decay and color shift caused by a KSF phosphor undergoing very serious degradation in high-temperature and high-humidity degradation and high-temperature environments”.

In some specific embodiments, when an input current is greater than or equal to 10 mA, the ratio of the peak wavelength intensity of the light of the first color (blue light) to the peak wavelength intensity of the light of the second color (green light) is greater than or equal to 5, preferably 5 to 10. After a red fluorescent film layer is provided on the surface of a blue-green dual-wavelength LED chip, packaging is performed to form a white LED. During the formation of a white light spectrum, a portion of blue light excites red fluorescence to form red light. Therefore, in the spectrum of the white LED, the peak intensity of the blue light will be significantly reduced, but the peak intensity of a green light spectrum remains basically unchanged. To meet the high color gamut requirement of the white LED, the peak intensity of the blue light in the white light spectrum also needs to meet a certain requirement. Therefore, during the setting of the blue-green dual-wavelength LED chip, it is necessary to set the ratio of the peak intensity of the wavelength of the blue light to the peak intensity of the wavelength of green light. FIG. 14 shows an optical power spectrum distribution under different currents.

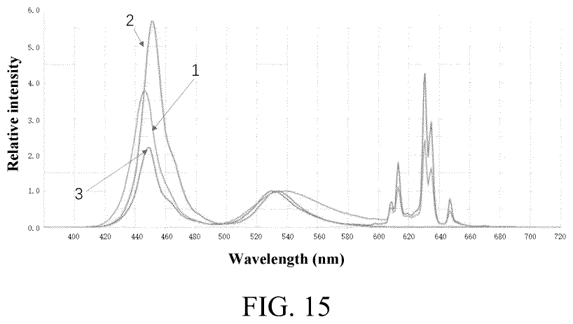

FIG. 15 shows a normalized-relative intensity spectrum of green light. Curve 1 is a monochromatic blue LED chip+green phosphor+red phosphor spectral curve; curve 2 is a blue-green dichromatic LED chip spectral curve; and curve 3 is a blue-green dichromatic LED chip+red phosphor spectral curve. Upon comparison of curve 1 with curve 3, the full width at half maximum of a green light spectrum in curve 3 is significantly less than that in curve 1. Upon comparison of curve 2 with curve 3, the peak intensity of blue light is lower, and the peak intensity of green light remains basically unchanged. Therefore, it can be determined that a red phosphor is mainly excited by the blue light.

Although the present invention is illustrated and described with reference to specific embodiments, it should be aware that the foregoing embodiments are merely intended for illustrating the technical solutions of the present invention, but not for limiting the present invention. A person of ordinary skill in the art should understand that modifications may be made to the technical solutions described in the foregoing embodiments, or equivalent substitutions may be made to some or all of technical features thereof, without departing from the spirit and scope of the present invention. These modifications or replacements do not cause the essence of corresponding technical solutions to depart from the scope of the technical solutions in embodiments of the present invention. therefore, this means that all these substitutions and modifications that fall within the scope of the present invention are included in the appended claims.

1. A single-chip polychromatic light-emitting diode, comprising a polychromatic light-emitting layer disposed between an N-type layer and a P-type layer, wherein
the polychromatic light-emitting layer comprises a first light-emitting layer emitting light of a first color and a second light-emitting layer emitting light of a second color, wherein the peak wavelength λₚ₂ of the light of the second color is greater than the peak wavelength λₚ₁ of the light of the first color, and λₚ₂−λₚ₁≥50 nm;
the thickness of a second well layer in the second light-emitting layer is less than the thickness of a first well layer in the first light-emitting layer; and
Al is doped between the second well layer and a second barrier layer in the second light-emitting layer, and the thickness of an Al-doped layer is less than ⅓ of the thickness of the second well layer.

2. The single-chip polychromatic light-emitting diode according to claim 1, wherein at least one of the following conditions is satisfied:
(1) the ratio of the thickness of the second well layer to the thickness of the first well layer is 0.5 to 0.95;
(2) the thickness of the second well layer is 27 Å to 32 Å; or
(3) the thickness of the first well layer is 33 Å to 38 Å.

3. The single-chip polychromatic light-emitting diode according to claim 1, wherein the first well layer comprises Inₓ₁Ga₍₁₋ₓ₁₎N, and the second well layer comprises Inₓ₂Ga₍₁₋ₓ₂₎N, wherein 1>x2>x1>0.1.

4. The single-chip polychromatic light-emitting diode according to claim 3, wherein x2=0.22−0.28; and/or x1=0.13−0.19.

5. The single-chip polychromatic light-emitting diode according to claim 1, wherein at least one of the following conditions is satisfied:
(1) the light of the first color comprises blue light, and the light of the second color comprises green light;
(2) the peak wavelength λₚ₁ of the light of the first color is equal to 440 nm to 470 nm;
(3) the peak wavelength λₚ₂ of the light of the second color is equal to 520 nm to 550 nm; and
(4) when an input current is greater than or equal to 10 mA, the ratio of the peak wavelength intensity of the light of the first color to the peak wavelength intensity of the light of the second color is greater than or equal to 5.

6. The single-chip polychromatic light-emitting diode according to claim 1, wherein the second light-emitting layer comprises second barrier layers, the first light-emitting layer comprises first barrier layers, and the single-chip polychromatic light-emitting diode satisfies at least one of the following conditions:
(1) the thickness of the second barrier layer is greater than the thickness of the first barrier layer;
(2) the thickness of the second barrier layer is 100 Å to 200 Å;
(3) the thickness of the first barrier layer is 90 Å to 100 Å;
(4) the ratio of a sum H2 of the thickness of the second well layer and the thickness of the second barrier layer to a sum H1 of the thickness of the first well layer and the thickness of the first barrier layer, that is, H2/H1, is equal to 0.9 to 1.1; or
(5) a ratio H3 of the thickness of the second barrier layer to the thickness of the second well layer is greater than or equal to a ratio H4 of the thickness of the first barrier layer to the thickness of the first well layer, and H3/H4=1−2.

7. The single-chip polychromatic light-emitting diode according to claim 1, wherein the first barrier layer in the first light-emitting layer comprises at least one of GaN, AlGaN, or InAlGaN;
and/or the second barrier layer in the second light-emitting layer comprises at least one of GaN, AlGaN, or InAlGaN.

8. The single-chip polychromatic light-emitting diode according to claim 1, wherein the number of first well layers is 10 to 20, and a first barrier layer is provided between every two adjacent first well layers;
and/or the number of second well layers is 1 to 5, and the second barrier layer is provided on each of two sides of each second well layer.

9. The single-chip polychromatic light-emitting diode according to claim 1, wherein the first light-emitting layer comprises a first periodic structure in which first well layers and first barrier layers are alternately stacked, and the number of periods of the first periodic structure is 10 to 20;
and/or the second light-emitting layer comprises a second periodic structure in which second well layers and second barrier layers are alternately stacked, and the number of periods of the second periodic structure is 1 to 5.

10. The single-chip polychromatic light-emitting diode according to claim 8, wherein the number of the first well layers is 4 times to 20 times the number of the second well layers.

11. The single-chip polychromatic light-emitting diode according to claim 1, wherein at least one of the following conditions is satisfied:
(1) the energy band of the second well layer in the second light-emitting layer is lower than the energy band of the first well layer in the first light-emitting layer;
(2) the energy band of the second barrier layer in the second light-emitting layer is lower than the energy band of the first barrier layer in the first light-emitting layer; or
(3) the direction from the N-type layer to the P-type layer is defined as a first direction, the energy band of the second barrier layer in the second light-emitting layer gradually increases in the first direction, and the energy band of the first barrier layer in the first light-emitting layer gradually decreases in the first direction.

12. The single-chip polychromatic light-emitting diode according to claim 1, wherein when an injected current is 350 mA, the brightness of the single-chip polychromatic light-emitting diode is greater than or equal to 770 mW.

13. An LED backlight source, wherein the LED backlight source comprises an RGB-LED and a white LED, and the RGB-LED or the white LED comprises the single-chip polychromatic light-emitting diode according to claim 1.

14. The LED backlight source according to claim 13, wherein at least one of the following conditions is satisfied:
(1) the RGB-LED comprises the single-chip polychromatic light-emitting diode and a monochromatic red light-emitting diode; or
(2) the white LED comprises the single-chip polychromatic light-emitting diode, a fluorescent film layer, and a high-reflective white adhesive around the single-chip polychromatic light-emitting diode and the fluorescent film layer, wherein the fluorescent film layer comprises a silicone layer and a red fluorescent layer; a red phosphor in the red fluorescent layer comprises a nitride phosphor and/or a fluoride phosphor; and when the red phosphor is a fluoride phosphor, the red fluorescent layer is further provided with a silicone protective layer on the side away from the single-chip polychromatic light-emitting diode.
